(19) United States
(12) Patent Application Publication
(10) Pub. No.: US 2023/0111323 A1
(43) Pub. Date: Apr. 13, 2023

(54) OXIDE LAYER DOPING ON A SUB CHANNEL OF A TRANSISTOR STRUCTURE

(71) Applicant: Intel Corporation, Santa clara, CA (US)

(72) Inventors: Rahul RAMAMURTHY, Hillsboro, OR (US); Ashish Verma PENUMATCHA, Beaverton, OR (US); Sarah ATANASOV, Beaverton, OR (US); Seung Hoon SUNG, Portland, OR (US); Inanc MERIC, Portland, OR (US); Uygar E. AVCI, Portland, OR (US)

(21) Appl. No.: 17/485,325

(22) Filed: Sep. 25, 2021

(51) Int. Cl. H01L 29/423; H01L 29/786; H01L 29/06; H01L 21/225

(52) U.S. Cl. CPC H01L 29/42392; H01L 21/2251; H01L 29/0665; H01L 29/78696

(57) ABSTRACT

Embodiments described herein may be related to apparatuses, processes, and techniques related to minimizing sub channel leakage within stacked GAA nanosheet transistors by doping an oxide layer on top of the sub channel. In embodiments, this doping may include selective introduction of charge species, for example carbon, within the gate oxide layer. Other embodiments may be described and/or claimed.

### FIELD

Embodiments of the present disclosure generally relate to the field of semiconductor packaging, and in particular to oxide layers on sub channels.

### BACKGROUND

Continued growth in virtual machines, cloud computing, and portable devices will continue to increase the demand for high density transistors within chips and packages.

### BRIEF DESCRIPTION OF THE DRAWINGS

FIG. 1 illustrates a gate all around (GAA) field effect transistor (FET) with stacked nanosheet transistors on a sub channel that includes a doped oxide, in accordance with various embodiments.

FIGS. 2A-2F illustrate manufacturing stages in a process for creating stacked nanosheet transistor on a sub channel that includes a doped oxide, in accordance with various embodiments.

FIGS. 3A-3G illustrate manufacturing stages in another process for creating stacked nanosheet transistor on a sub channel that includes a doped oxide, in accordance with various embodiments.

FIG. 4 illustrates an example process for creating a stacked nanosheet transistor on a sub channel that includes a doped oxide, in accordance with various embodiments.

FIG. 5 illustrates a computing device 500 in accordance with one implementation of the invention.

FIG. 6 illustrates an interposer 600 that includes one or more embodiments of the invention.

### DETAILED DESCRIPTION

Embodiments described herein may be related to apparatuses, processes, and techniques directed to minimizing sub channel leakage within stacked GAA nanosheet transistors by introducing dopants in oxide layer on top of the sub channel. In embodiments, this doping may include selective introduction of charge species, for example carbon, within the gate oxide layer. In embodiments, the doping may be referred to as introducing electrically active defects into the gate oxide layer. By doping the oxide layer next to the sub channel, which may also be referred to as a parasitic transistor, and not doping oxide layers in the channels above the sub channel, this will in effect turn off or greatly reduce leakage in the sub channel. This may also be referred to as reducing the electric participation of the sub channel. As a result, in embodiments, power dissipation is decreased and performance of GAA transistors is improved.

In legacy implementations of stacked GAA nanosheet transistors, sub channel leakage is a limiting aspect that affects performance and usability. Sub channel leakage includes a parasitic leakage path due to inferior electrostatics at the sub channel, or the bottom-most surface, which could be a silicon substrate. Sub channel leakage is analogous to sub-fin leakage in FinFET devices. Legacy techniques to reduce sub-fin leakage may be used in GAA devices in attempt to solve the sub channel leakage. One of these legacy techniques include doping of the silicon substrate both under the channels above the sub channel to increase the local threshold voltage and under the epitaxial layers (source/drain) to reduce punch through or leakage under the contacts. Another legacy technique is to use a thick dielectric on the sub channel to isolate the sub channel (substrate) from both the channel and source/drain contacts. This technique controls the electric field in a lateral or horizontal direction with respect to a top surface of the sub channel. These legacy implementations not only produce additional complexity to manufacturing process flow, but also require tighter controls during manufacturing. Embodiments described herein may be used to control the electric field in a direction perpendicular to the top surface of the sub channel by creating a local dipole in the oxide, therefore improving reliability.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

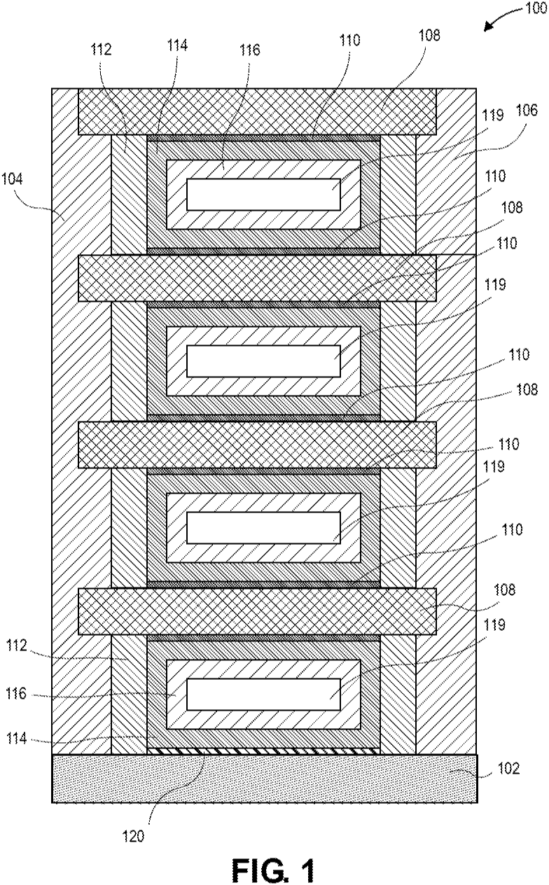

FIG. 1 illustrates a GAA FET with stacked nanosheet transistors on a sub channel that includes a doped oxide, in accordance with various embodiments. GAA FET 100 includes a sub channel 102, which may also be referred to as a substrate 102 that is in contact with a source 104 and a drain 106. In embodiments, the source 104 may be referred to as an epitaxial source, and the drain 106 may be referred to as an epitaxial drain. A plurality of channels 108 are above the sub channel 102, and also coupled with the source 104 and the drain 106. In embodiments, the channels 108 may be nanoribbons or nanosheets that may include silicon.

In embodiments, an oxide layer 110, which may also be referred to as a gate oxide, may be coupled with each of the channels 108. The area between each of the channels 108 may include a spacer 112, a dielectric 114, which may be a high-k dielectric and a metal gate 116. In embodiments, a conductor 119 may be included inside the metal gate 116, and may be used for interconnects. Note that each of the oxide layers 110 maybe legacy oxide layers without any special doping or electrically active defects, such as carbon atoms, added.

Oxide layer 120, above sub channel 102, has been modified to include electrically active defects, such as carbon atoms, within the oxide layer 120. In embodiments, the oxide layer 120 may be referred to as having been doped. Because these active defects are introduced within the oxide layer 120, they electrically modify the control voltage, the voltage at which a transistor will turn on, for the sub channel 102 and make the control voltage large enough so that the transistor of the sub channel 102 will not turn on, even though the channels 108 will turn on. This may also be referred to as suppressing sub channel 102 leakage.

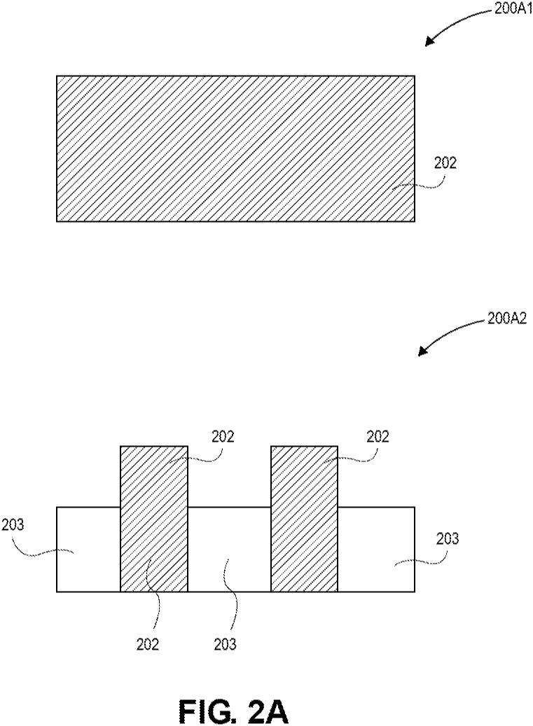

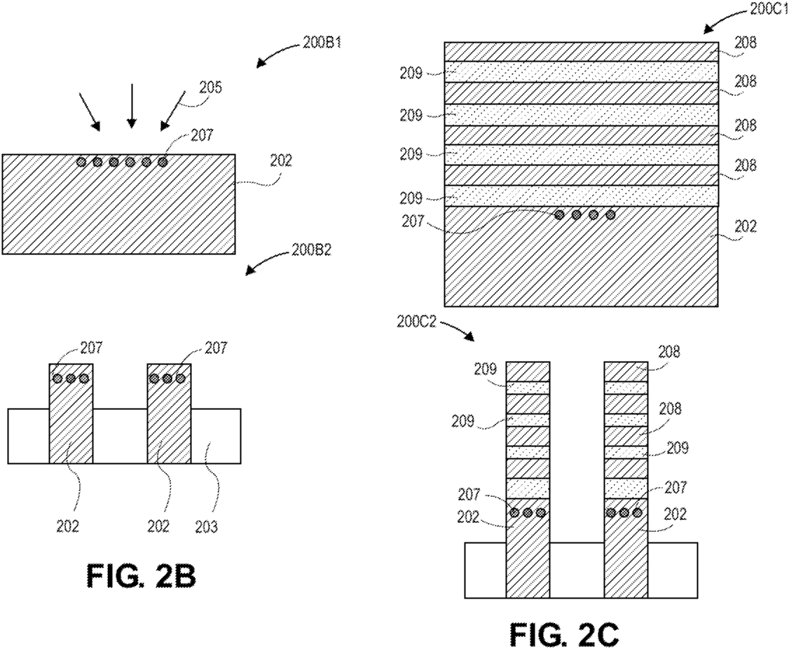

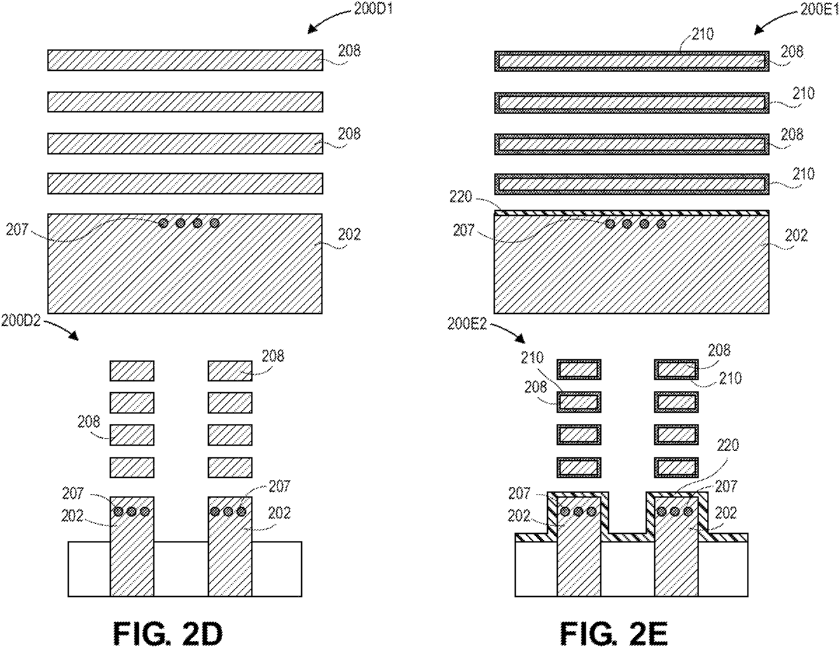

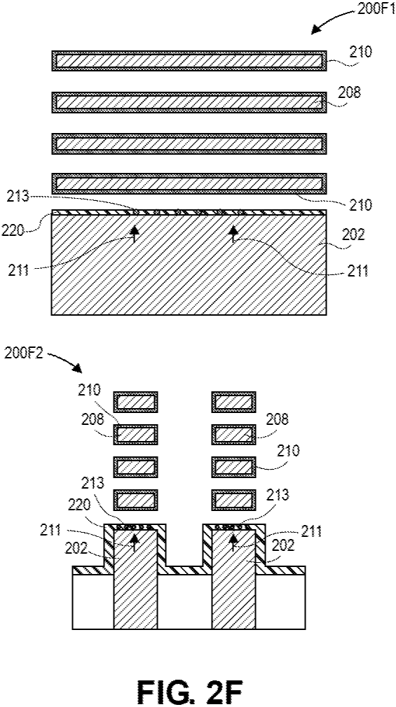

FIGS. 2A-2F illustrate manufacturing stages in a process for creating stacked nanosheet transistor on a sub channel that includes a doped oxide, in accordance with various embodiments. FIG. 2A includes first cross section side view 200A1 and an orthogonal cross section side view 200A2 of a sub channel 202, that may be similar to sub channel 102 of FIG. 1. Sub channel 202 may include silicon, and may be part of a polysilicon layer 203.

FIG. 2B includes a first cross section side view 200B1 and an orthogonal cross section side view 200B2 of the result of a implanting process indicated by arrows 205 used to implant atoms 207 below a surface of the sub channel 202. The implanted atoms 207 may also be referred to as introducing species or introducing defects within the sub channel 202 embodiments, carbon atoms may be used because they form electrically active defect levels that are favorable to reduce the leakage in the local sub channel region, and do not affect other parts of the transistor.

FIG. 2C includes a first cross section side view 200C1 and an orthogonal cross section side view 200C2 that show the buildup of multiple channels. In embodiments, layers of a sacrificial material 209, that may include silicon germanium (SiGe), may be progressively placed and onto which channels 208, which may be similar to channels 108 of FIG. 1, may be formed. As shown, four channels 208 are created. In embodiments, these channels 208 may include silicon, or some other semiconductors suited for FET devices like Ge and may also include 2D materials such as WSe2, Ws2 etc. In embodiments, the channels 208 may be nanowires, nanosheets or nanoribbons. In embodiments, the application of the sacrificial material 209 will not significantly affect the positioning of the atoms 207 within the sub channel 202. Note that for clarity of illustration for FIGS. 2C-2F, other portions of the transistor shown in FIG. 1 may not be shown.

FIG. 2D includes a first cross section side view 200D1 and an orthogonal cross section side view 200D2 where the sacrificial material 209 from FIG. 2C is removed, leaving the channels 208 above the sub channel 202.

FIG. 2E includes a first cross section side view 200E1 and an orthogonal cross section side view 200E2 where an oxide layer 210 is placed around the channels 208 and an oxide layer 220 is placed over the sub channel 202. The oxide layer 210, 220, which may be similar to oxide layer 110, 120 of FIG. 1, may be deposited using atomic layer deposition(ALD) or chemical vapor deposition (CVD) techniques. The oxide layer 210, 220 may also be referred to as a gate oxide layer, and may be the same oxide material, that may include dielectrics used as gate oxides such as aluminum oxide, silicon-germanium oxide, zirconium oxide.

FIG. 2F includes a first cross section side view 200F1 and an orthogonal cross section side view 200F2 where an annealing process is applied to provide heat which will cause the atoms 207 of FIG. 2E to migrate in a direction 211 to form atoms 213 within the oxide layer 220. These defects segregate in the oxide and remain local to the sub channel region. In embodiments, there may be some atoms 207 of FIG. 2E within sub channel 202 that have not fully migrated into the oxide layer 220. As a result of the annealing process, a better quality oxide 210 is formed around the channels 208 increasing their electrical performance, and the doped oxide layer 220 above the sub channel 202 decreases its electrical performance, thereby reducing electrical leakage through the sub channel 202.

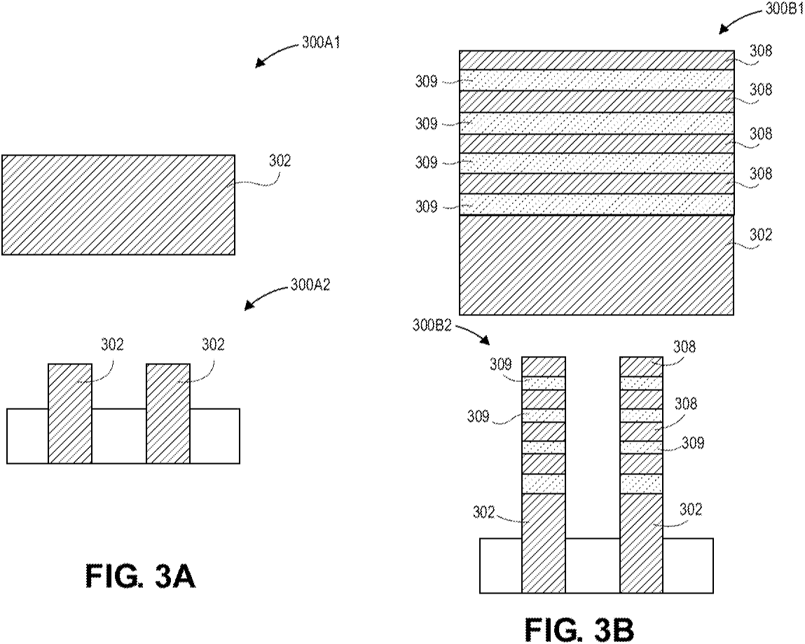

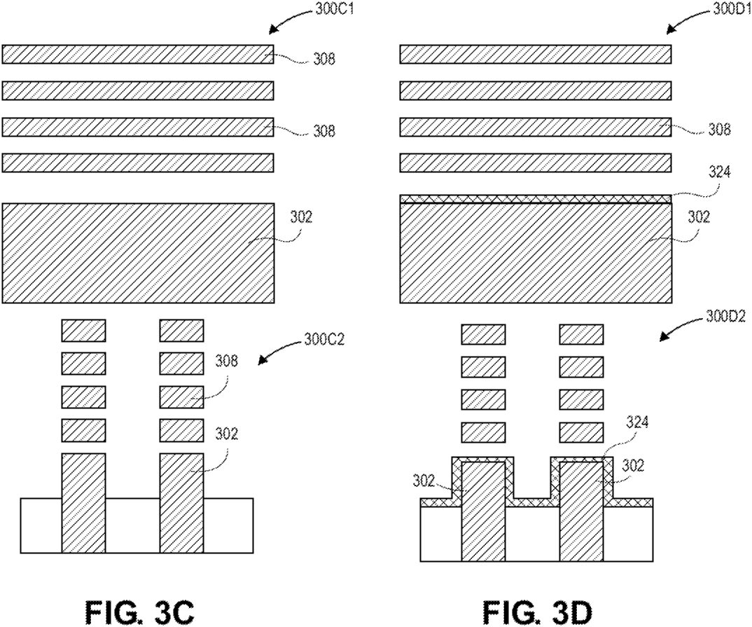

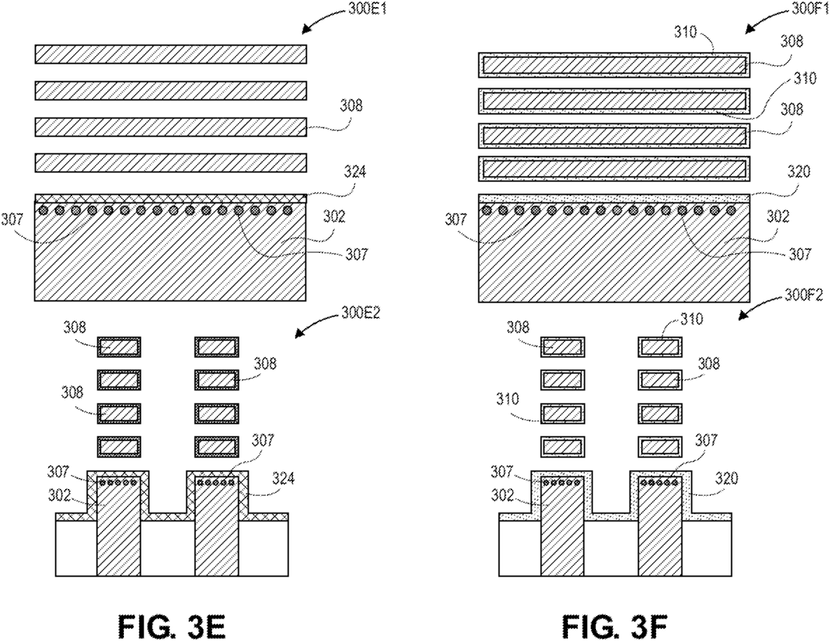

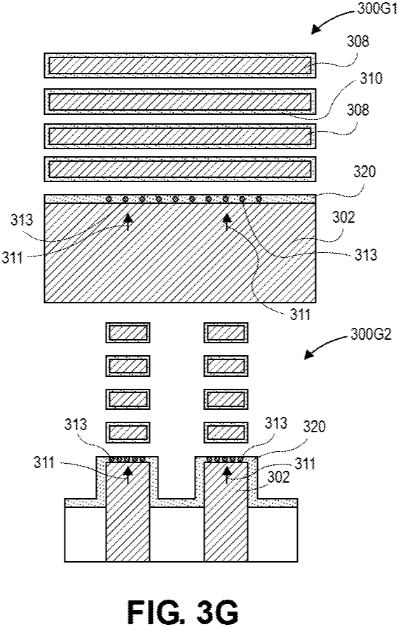

FIGS. 3A-3G illustrate manufacturing stages in another process for creating stacked nanosheet transistor on a sub channel that includes a doped oxide, in accordance with various embodiments. FIG. 3A includes first cross section side view 300A1 and an orthogonal cross section side view 300A2 of a sub channel 302, that may be similar to sub channel 102 of FIG. 1. Sub channel 302 may include silicon, and may be part of a polysilicon layer 303.

FIG. 3B includes a first cross section side view 300B1 and an orthogonal cross section side view 300B2 that show the buildup of multiple channels. In embodiments, layers of a sacrificial material 309, which may be similar to sacrificial material 209 of FIG. 2C, that may include SiGe, may be progressively placed onto which channels 308, which may be similar to channels 108 of FIG. 1. As shown, four channels 308 are created. In embodiments, these channels 308 may include silicon, silicon-germanium, germanium or some other material suitable for channels such as 2D materials. In embodiments, the channels 308 may be nanowires, nanosheets or nanoribbons. Note that for clarity of illustration for FIGS. 3B-3G, other portions of the transistor shown in FIG. 1 may not be shown.

FIG. 3C includes a first cross section side view 300C1 and an orthogonal cross section side view 300C2 where the sacrificial material 309 from FIG. 3B is removed, leaving the channels 308 above the sub channel 302.

FIG. 3D includes a first cross section side view 300D1 and an orthogonal cross section side view 300D2 where a layer of electrically active defects 324 is applied onto the sub channel 302. In embodiments, the layer 324 may be applied using atomic layer deposition (ALD) process. The layer 324 may include carbon atoms, for example C₆H₁₉N₃Si.

FIG. 3E includes a first cross section side view 300E1 and an orthogonal cross section side view 300E2 where a flare/flash anneal process is applied. In embodiments, this anneal process may be performed in an inert ambient such as an argon (Ar) ambient, which disassociates the long carbon ligands in the layer of electrically active defects 324 that may then be chemisorbed into the surface of the sub channel 302 as dimers. As a result, the atoms 307, which may be carbon atoms, are moved into the surface of the sub channel 302.

FIG. 3F includes a first cross section side view 300F1 and an orthogonal cross section side view 300F2 where the layer of electrically active defects 324 is removed, and an oxide layer 310, which may be similar to oxide layer 210 of FIG. 2E is placed around the channels 308 and an oxide layer 320, which may be similar to oxide layer 220 of FIG. 2E, is placed over the sub channel 302. The oxide layers 310, 320, may be deposited using atomic layer deposition (ALD) or chemical vapor deposition (CVD) techniques. The oxide layer 310, 320 may also be referred to as a gate oxide layer, and may be the same oxide material, that may include silicon di-oxide, aluminum oxide etc.

FIG. 3G includes a first cross section side view 300G1 and an orthogonal cross section side view 300G2 where an annealing process is applied to provide heat which will cause the atoms 307 of FIG. 3F to migrate in a direction 311 to form atoms 313 within the oxide layer 320. In embodiments, there may be some atoms 307 of FIG. 3F within sub channel 302 that have not fully migrated into the oxide layer 320. As a result of the annealing process, a better quality oxide layer 310 is formed around the channels 308 increasing their electrical performance, and the doped oxide layer 320 above the sub channel 302 decreases its electrical performance, thereby reducing electrical leakage through the sub channel 302.

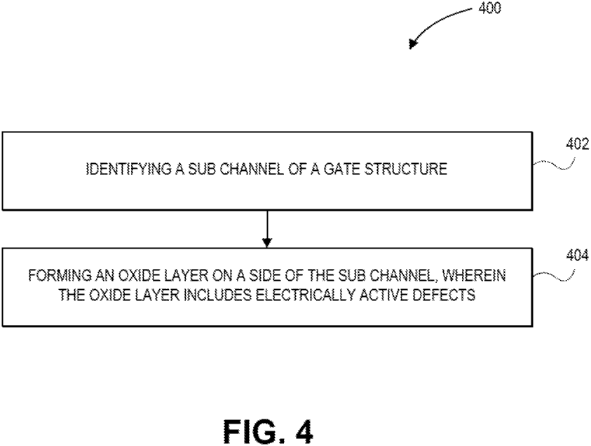

FIG. 4 illustrates an example process for creating a stacked nanosheet transistor on a sub channel that includes a doped oxide, in accordance with various embodiments. Process 400 may be performed using the techniques, processes, apparatus, and/or systems as described herein and particularly with respect to FIGS. 1-3G.

At block 402, the process may include identifying a sub channel of a gate structure.

At block 404, the process may further include forming an oxide layer on a side of the sub channel, wherein the oxide layer includes electrically active defects.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or gate-all-around transistors such as nanoribbon and nanowire transistors. Although the implementations described herein may illustrate only Finfet transistors, it should be noted that the invention may also be carried out using planar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO2) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

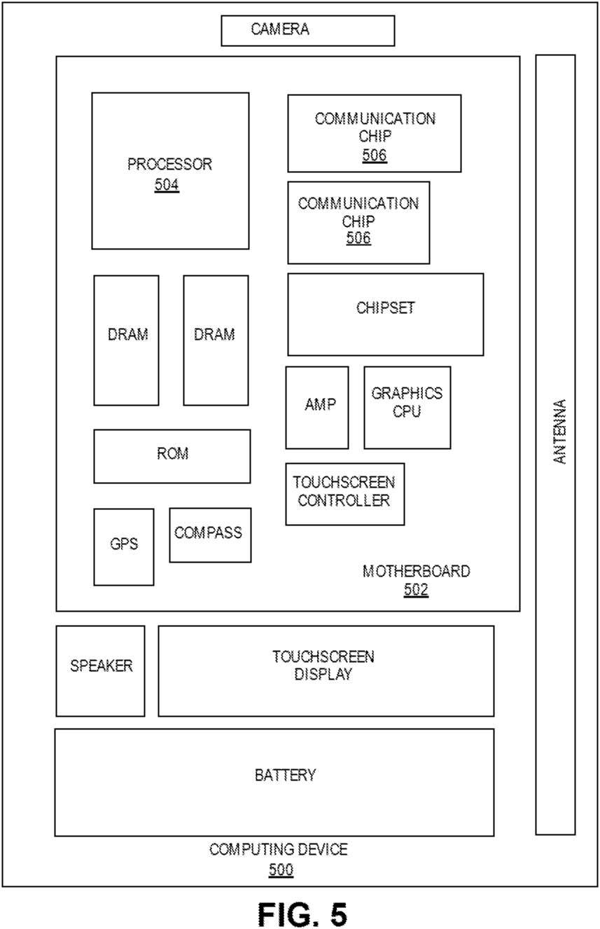

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip includes one or more devices, such as MOS-FET transistors built in accordance with implementations of the invention.

In further implementations, another component housed within the computing device 500 may contain an integrated circuit die that includes one or more devices, such as MOS-FET transistors built in accordance with implementations of the invention.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

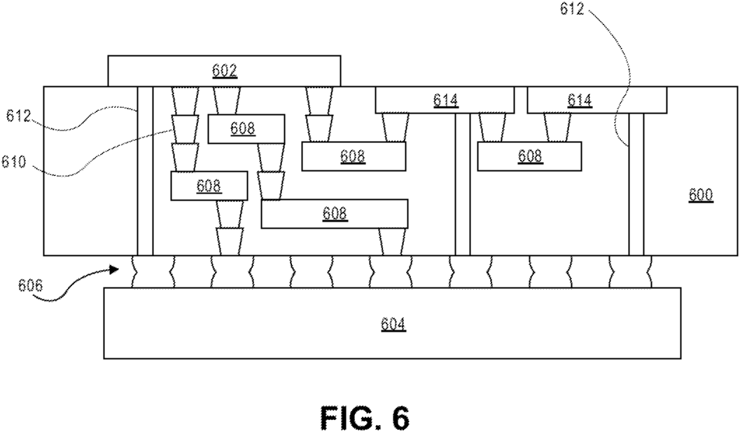

FIG. 6 illustrates an interposer 600 that includes one or more embodiments of the invention. The interposer 600 is an intervening substrate used to bridge a first substrate 602 to a second substrate 604. The first substrate 602 may be, for instance, an integrated circuit die. The second substrate 604 may be, for instance, a memory module, a computer motherboard, or another integrated circuit die. Generally, the purpose of an interposer 600 is to spread a connection to a wider pitch or to reroute a connection to a different connection. For example, an interposer 600 may couple an integrated circuit die to a ball grid array (BGA) 606 that can subsequently be coupled to the second substrate 604. In some embodiments, the first and second substrates 602/604 are attached to opposing sides of the interposer 600. In other embodiments, the first and second substrates 602/604 are attached to the same side of the interposer 600. And in further embodiments, three or more substrates are interconnected by way of the interposer 600.

The interposer 600 may be formed of an epoxy resin, a fiberglass-reinforced epoxy resin, a ceramic material, or a polymer material such as polyimide. In further implementations, the interposer 600 may be formed of alternate rigid or flexible materials that may include the same materials described above for use in a semiconductor substrate, such as silicon, germanium, and other group III-V and group IV materials.

The interposer 600 may include metal interconnects 608 and vias 610, including but not limited to through-silicon vias (TSVs) 612. The interposer 600 may further include embedded devices 614, including both passive and active devices. Such devices include, but are not limited to, capacitors, decoupling capacitors, resistors, inductors, fuses, diodes, transformers, sensors, and electrostatic discharge (ESD) devices. More complex devices such as radiofrequency (RF) devices, power amplifiers, power management devices, antennas, arrays, sensors, and MEMS devices may also be formed on the interposer 600. In accordance with embodiments of the invention, apparatuses or processes disclosed herein may be used in the fabrication of interposer 600.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### EXAMPLES

Example 1 is a gate structure comprising: a sub channel; and an oxide layer on a side of the sub channel, wherein the oxide layer includes electrically active defects.

Example 2 includes the gate structure of example 1, wherein the electrically active defects include carbon atoms.

Example 3 includes the gate structure of example 1, further comprising a channel above the sub channel, wherein the channel includes an oxide layer that does not include electrically active defects.

Example 4 includes the gate structure of example 3, wherein the channel is a nanoribbon.

Example 5 includes the gate structure of example 4, wherein the nanoribbon is a silicon nanoribbon.

Example 6 includes the gate structure of example 2, further comprising a source and a drain that electrically couple the sub channel with the channel.

Example 7 includes the gate structure of example 1, wherein the sub channel includes silicon.

Example 8 includes the gate structure of example 1, wherein the sub channel is a portion of a substrate.

Example 9 includes the gate structure of example 1, wherein a portion of the sub channel proximate to the oxide layer includes electrically active defects.

Example 10 includes the gate structure of any one of examples 1-9, wherein the gate structure is a portion of a gate all around (GAA) transistor structure.

Example 11 is a method comprising: identifying a sub channel of a gate structure; and forming an oxide layer on a side of the sub channel, wherein the oxide layer includes electrically active defects.

Example 12 includes the method of example 11, wherein forming an oxide layer further includes: implanting electrically active defects into a side of the sub channel; applying an oxide layer to the side of the sub channel; and moving at least a portion of the electrically active defects into the oxide layer by performing an annealing process.

Example 13 includes the method of example 12, wherein after implanting electrically active defects, the method further comprising: applying a sacrificial layer to the side of the sub channel; forming a channel on top of the sacrificial layer; removing the sacrificial layer; and applying an oxide layer to a side of the formed channel.

Example 14 includes the method of example 13, wherein the sacrificial layer includes silicon and germanium.

Example 15 includes the method of example 13, wherein the sub channel and the channel include silicon.

Example 16 includes the method of example 11, wherein forming an oxide layer further includes: applying a layer that includes electrically active defects to the side of the sub channel; moving at least a portion of the electrically active defects within the applied layer into the sub channel by performing an annealing process; removing the applied layer to expose the side of the sub channel; applying an oxide layer on the side of the sub channel; and moving at least a portion of the electrically active defects in the sub channel into the oxide layer by performing an annealing process.

Example 17 includes the method of example 16, wherein the applied layer includes a selected one or more of carbon, hydrogen, nitrogen, and/or silicon.

Example 18 includes the method of example 16, wherein after applying the layer that includes electrically active defects, the method further comprising: applying a sacrificial layer to a side of the applied layer opposite the sub channel; forming a channel on top of the sacrificial layer; and removing the sacrificial layer.

Example 19 includes the method of example 18, wherein applying an oxide layer on the side of the sub channel further includes applying the oxide layer on a side of the channel.

Example 20 includes the method of any one of example 16-19, wherein the sub channel is a portion of a silicon substrate.

Example 21 is a transistor comprising: a sub channel; a plurality of channels above the sub channel; a source coupled with the sub channel and coupled with a portion, respectively, of the plurality of channels; a drain coupled with the sub channel and coupled with another portion, respectively, of the plurality of channels; an oxide layer, respectively, on each of the plurality of channels; and an oxide layer on the sub channel, wherein the oxide layer on the sub channel includes dopants.

Example 22 includes the transistor of example 21, wherein the doping includes carbon atoms.

Example 23 includes the transistor of example 21, wherein the plurality of channels above the sub channel are silicon nanoribbons.

Example 24 includes the transistor of example 21, wherein the oxide layer on each of the plurality of channels includes doping below a threshold level of 5E14cm-2.

Example 25 includes the transistor of any one of examples 21-24, wherein the sub channel is a portion of a silicon substrate.

1-25. (canceled)

26. An apparatus comprising:
a gate all around (GAA) field effect transistor (FET) that includes:
a sub channel coupled with a source and a drain;
a channel above the sub channel, the channel coupled with the source and the drain, wherein the channel includes a nanowire; and
a dielectric layer comprising oxygen on a side of the sub channel between the channel and the sub channel, wherein the dielectric layer comprising oxygen includes a dopant.

27. The apparatus of claim 26, wherein the dopant includes carbon atoms.

28. The apparatus of claim 26, wherein the dopant includes electrically active defects.

29. The apparatus of claim 26, wherein the channel includes a dielectric layer that does not include the dopant.

30. The apparatus of claim 29, wherein the channel includes a first side and a second side opposite the first side; and wherein the dielectric layer of the channel is on the first side and the second side of the channel.

31. The apparatus of claim 26, wherein the nanowire is a silicon nanowire.

32. The apparatus of claim 26, wherein the channel is a plurality of channels above the sub channel.

33. The apparatus of claim 26, wherein the sub channel includes silicon.

34. The apparatus of claim 26, wherein the sub channel is a portion of a substrate.

35. The apparatus of claim 26, wherein a portion of the sub channel proximate to the dielectric layer comprising oxygen of the sub channel includes the dopant.

36. A method comprising:
providing a sub channel of a GAA FET gate structure; and
forming a dielectric layer comprising oxygen on a side of the sub channel, wherein the dielectric layer comprising oxygen includes a dopant.

37. The method of claim 36, wherein forming the dielectric layer comprising oxygen further includes:
implanting a dopant into a side of the sub channel;
applying the dielectric layer comprising oxygen to the side of the sub channel; and
moving at least a portion of the implanted dopant into the dielectric layer comprising oxygen by performing an annealing process.

38. The method of claim 37, wherein after implanting the dopant, the method further comprising:
applying a sacrificial layer to the side of the sub channel;
forming a channel on top of the sacrificial layer;
removing the sacrificial layer; and
applying the dielectric layer comprising oxygen to a side of the formed channel.

39. The method of claim 38, wherein the sacrificial layer includes silicon and germanium.

40. The method of claim 38, wherein the sub channel and the channel include silicon.

41. The method of claim 36, wherein forming the dielectric layer comprising oxygen further includes:
applying a layer that includes a dopant to the side of the sub channel;
moving at least a portion of the dopant within the applied layer into the sub channel by performing an annealing process;
removing the applied layer to expose the side of the sub channel;
applying the dielectric layer comprising oxygen on the side of the sub channel; and
moving at least a portion of the dopant in the sub channel into the dielectric layer comprising oxygen by performing an annealing process.

42. The method of claim 41, wherein the applied layer includes a selected one or more of carbon, hydrogen, nitrogen, and/or silicon.

43. The method of claim 41, wherein after applying the layer that includes the dopant, the method further comprising:
applying a sacrificial layer to a side of the applied layer opposite the sub channel;
forming a channel on top of the sacrificial layer; and
removing the sacrificial layer.

44. The method of claim 43, wherein applying the dielectric layer comprising oxygen on the side of the sub channel further includes applying the dielectric layer comprising oxygen on a side of the channel.

45. The method of claim 43, wherein the sub channel is a portion of a silicon substrate.

46. A GAA FET comprising:
a sub channel;
a plurality of channels above the sub channel;
a source coupled with the sub channel and coupled with a portion, respectively, of the plurality of channels;
a drain coupled with the sub channel and coupled with another portion, respectively, of the plurality of channels;
an oxide layer, respectively, on each of the plurality of channels; and
an oxide layer on the sub channel, wherein the oxide layer on the sub channel includes a dopant.

47. The transistor of claim 46, wherein the dopant includes carbon atoms.

48. The transistor of claim 46, wherein the plurality of channels above the sub channel are nanoribbons.

49. The transistor of claim 46, wherein the oxide layer on each of the plurality of channels includes doping below a threshold level of 5E14cm⁻².

50. The transistor of claim 46, wherein the sub channel is a portion of a silicon substrate.
